(19) United States
(12) Patent Application Publication
(10) Pub. No.: US 2009/0300439 A1
(43) Pub. Date: Dec. 3, 2009

(54) Method and Apparatus for Testing Write-Only Registers

(76) Inventor: Christopher Haywood, Thousand Oaks, CA (US)

Correspondence Address: SoCAL IP LAW GROUP LLP, 310 N. WESTLAKE BLVD. STE 120, WESTLAKE VILLAGE, CA, 91362, US

(21) Appl. No.: 12/132,488

(22) Filed: Jun. 3, 2008

(51) Int. Cl. G11C 29/00; G06F 11/22

(52) U.S. Cl. 714/718; 714/E11.145

(57) ABSTRACT

There is disclosed a test circuit for testing an integrated circuit containing at least one write-only register and providing at least one output signal through at least one output pin. The test circuit may include a test mode decoder circuit to enable a test mode and a data selector circuit to select at least a portion of data stored in the at least one write-only register as test data. The test data may be output from the integrated circuit through the at least one output pin.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

1. Field

This disclosure relates to the testing of integrated circuits containing write-only registers.

2. Description of the Related Art

Complex integrated circuit (IC) devices may be configurable by means of writable control registers that store configuration and control information to control, at least in part, the function of the IC. Data may be written to such control registers during system initialization. These control registers may commonly be “write-only” registers, in that there may be no defined protocol for reading the values stored in the registers.

For example, emerging JEDEC standards have defined configurable memory subsystems that have configurable enable and timing functions and I/O drive levels depending on the memory configuration discovered at system boot. These functions are configured by setting register values within a memory register IC during system initialization. However, there is no definition of any read function to validate that the specific memory subsystem functions are being controlled correctly, or that the registers required to control the memory subsystem functions are actually capable of doing so.

### DESCRIPTION OF THE DRAWINGS

FIG. 1 is a block diagram of an integrated circuit.

FIG. 2 is a block diagram of an integrated circuit.

FIG. 3 is a block diagram of an exemplary memory register integrated circuit.

FIG. 4 is a flow chart of a process for testing an integrated circuit.

FIG. 5 is a flow chart of a process for testing an integrated circuit.

FIG. 6 is a flow chart of a process for testing an integrated circuit.

Throughout this description, elements appearing in figures are assigned three-digit reference designators, where the most significant digit is the figure number and the two least significant digits are specific to the element. An element that is not described in conjunction with a figure may be presumed to have the same characteristics and function as a previously-described element having a reference designator with the same least significant digits.

### DETAILED DESCRIPTION

Description of Apparatus

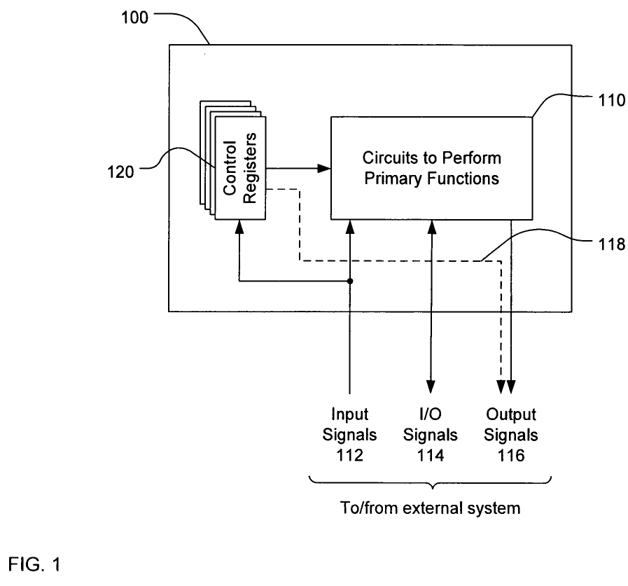

Referring now to FIG. 1, an integrated circuit 100 may include circuits 110 to perform one or more primary functions and one or more control registers 120 storing control data used to configure or otherwise control, at least in part, the performance of the primary functions. The integrated circuit 100 may receive input signals 112 from an external system (not shown), may exchange bidirectional input/output (I/O) signals 114 with the external system, and may provide output signals 116 to the external system. The primary functions performed by circuits 110 may include any form of manipulating, modifying, storing, and/or processing of the input signals 112 and incoming I/O signals 114 as required to provide the output signals 116 and outgoing I/O signals 114.

The primary functions performed by circuits 110 may be configured by control data written into the control registers 120. The control data may be written into the control registers 120 using only the input signals 112, such that the control registers 120 have no internal connection to the I/O signals 114 or the output signals 116 during normal operation of the integrated circuit 100. Thus the control registers 120 may be intrinsically write-only registers in that there may be no inherent path to the external system by which to read or verify the content of the control registers.

Additional output and input signals could be added to the integrated circuit 100 to facilitate testing the control registers 120. However, adding additional signal pins may have an adverse effect on the cost of the integrated circuit 100, since the area of the integrated circuit chip may be determined, at least in part, by the perimeter length required to provide the input, output, and I/O signal connections.

The dashed line 118 indicates a test signal path, not required for normal operation of the integrated circuit, that may be incorporated to allow the content of the control registers to be read and verified by the external system. The test path 118 may be active only during a defined test mode, and may output at least a portion of the content of the control registers 120 in place of existing output signals 116 or I/O signals 114. The test mode may be enabled using only existing input or I/O signals. Thus the controls registers 120 may be tested by the external system using only existing input, I/O, and output signals, where “existing signals” specifically means signals that are already provided and required for the normal, non-test, operation of the integrated circuit 100.

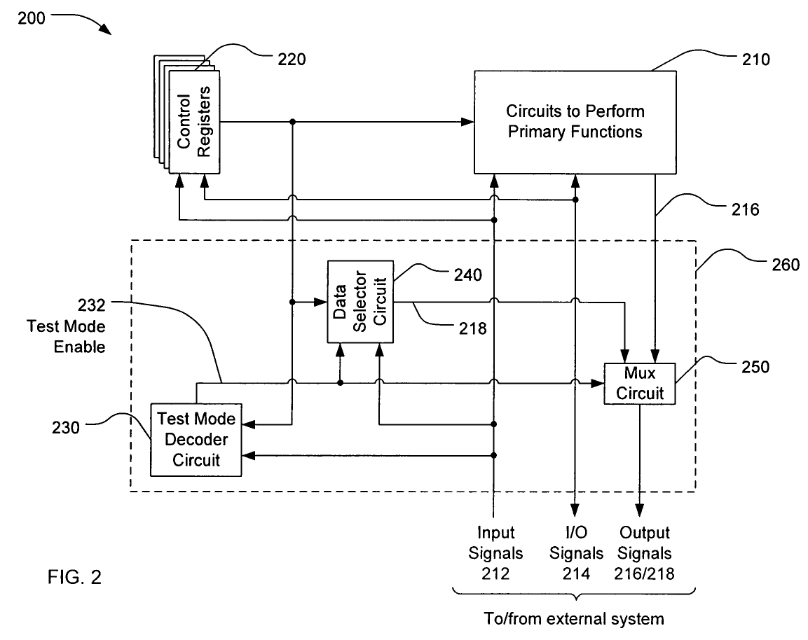

Referring now to FIG. 2, an exemplary integrated circuit 200 may include circuits 210 to perform one or more primary functions and one or more control registers 220 to store control data that configures and controls, at least in part, the performance of the primary functions. The integrated circuit 200 may receive input signals 212 from an external system (not shown), may exchange bidirectional input/output (I/O) signals 214 with the external system, and may provide output signals 216 to the external system. The primary functions performed by the circuits 210 may include any form of manipulating, modifying, storing, and/or processing of the input signals 212 and incoming I/O signals 214 as required to provide the output signals 216 and outgoing I/O signals 214.

The primary functions may be configurable by means of control data written into the control registers 220. The control data may be written into the control registers 220 using only the input signals 212. The integrated circuit 200 may include test circuits, enclosed by dashed line 260, to enable the content of the control registers 220 to be verified by the external system.

The test circuits may include a test mode decoder circuit 230 to detect when a test mode has been enabled by the external system. The test mode may be enabled by the external system providing a combination of input signals that are not defined or used during the normal operation of the integrated circuit 100. For example three binary input signals may be provided to select one of six functions of the integrated circuit. Since only six of the eight possible combinations of the three binary input signals are required during normal operation of the integrated circuit, one of the two unused combinations could be used to enable a test mode. Similarly, a test mode may be enabled by the external system by storing, in the one or more control registers, control data that is not defined or used during the normal operation of the integrated circuit 200. Thus the test mode decoder circuit 230 may detect that a test mode is enabled by evaluating the input signals 212, the control data stored in the control registers 220, or a combination of input signals and stored control data.

In some cases, undefined or unused combinations of inputs signals and/or stored control data may be reserved for future use. A reserved combination of input signals and/or stored control data may be used to enable a test mode, but with the risk of loss of compatibility with future versions of the integrated circuit 200.

A plurality of test modes may be used to effect complete testing of the control registers 220. The test mode decoder circuit 230 may detect a plurality of input signal and/or stored control data combinations to enable a corresponding plurality of test modes, each of which allows testing of some corresponding portion of the control registers 220. Once the test mode decoder circuit 230 detects a combination of input signals and/or stored data that enables a test mode, the integrated circuit 200 may be placed in a test mode only so long as the combination of input signals and/or stored data is maintained. Alternatively, the test mode decoder circuit 230 may detect a first predetermined input signal and/or stored data combination to cause the integrated circuit 200 to enter a test mode that is held until the test mode decoder circuit 230 detects a second predetermined input signal and/or stored data combination to exit the test mode.

Once the integrated circuit 200 has entered a test mode, a data selector circuit 240 may be enabled to select at least a portion of the data in the control registers 220 for verification. For example, if the control registers 220 store a total of 32 bits, the data selector circuit 240 may select a single bit, pairs of bits, 4-bit nibbles, or 8-bit bytes as test data 218 for verification. The data selector circuit 240 may be a multiplexer, a shift register, or other logic circuits to selected the desired number of bits from the control registers 220. At least some of the input signals 212 may be coupled to the data selector circuit 240 to control which bits are selected from the control registers 220. For example, if the control registers 220 store a total of 32 bits and a single bit is to be output for verification, five input signals may be coupled to the data selector circuit 240 to define the selected bit.

During the test mode, the test data 218 selected by the data selector circuit 240 may be coupled to a corresponding number of output signal lines 216 by multiplexer circuit 250. During a test mode, the multiplexer circuit 250 may simply substitute the test data 218 for the normal output signals 216 from the circuits 210. During normal operation of the integrated circuit 200, the multiplexer circuit 250 may pass the normal output signals 216 to the external system. The multiplexer circuit 250 may be a specific circuit, or may be implemented by routing the signals 216 and 218 onto a common signal bus using tri-state logic.

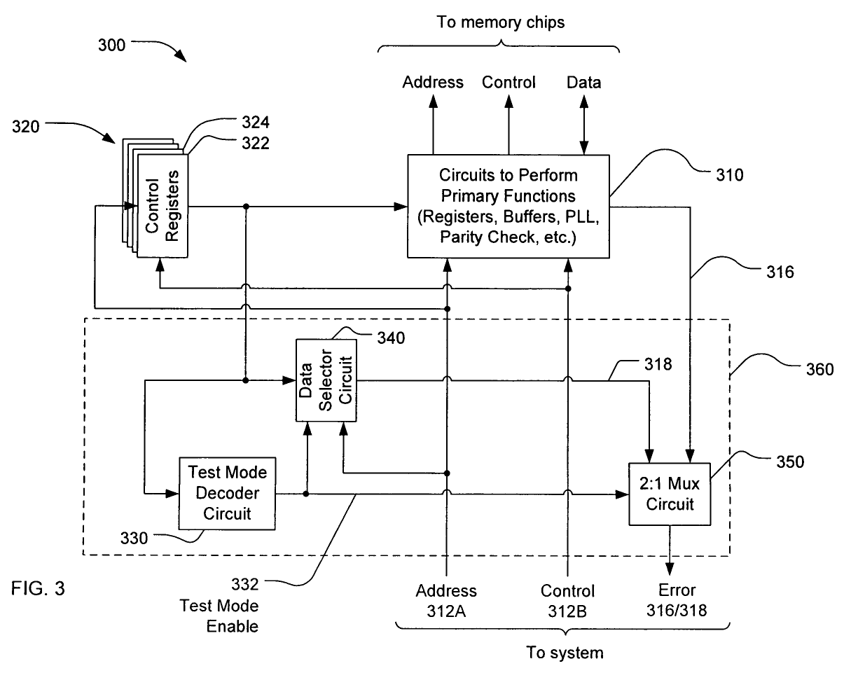

Referring now to FIG. 3, a memory controller 300 is shown as a specific example of an integrated circuit containing read-only registers. The memory controller 300 may include circuits 310, which may include registers, buffers, and other circuits, required to interface between a system (not shown) and a plurality of dynamic random access memory chips (not shown). The memory controller 300 may be, for example, compatible with the JEDEC DDR3 memory specification. The memory controller 300 may include a plurality of control registers 320 to store control data that configures and controls, at least in part, the performance of the circuits 310. The memory controller 300 may receive address input signals 312A and control input signals 312B from the external system. The circuits 310 may include parity check circuits or other error detection mechanisms to provide an error output signal 316 to the external system. The memory controller 300 may provide other output signals (not shown) to the external system.

The circuits 310 performing the primary functions may be configurable by means of control data written into the control registers 320. The control data may be written by storing the address inputs 312A into the control registers 320 under control of the control inputs 312B. The memory controller 300 may include test circuits, enclosed by dashed line 360, to enable the content of the control registers 320 to be verified by the external system.

The test circuits may include a test mode decoder circuit 330 to detect when a test mode has been requested by the external system. The test mode may be requested by the external system by storing, in the one or more control registers, control data that is undefined or otherwise not used during the normal operation of the memory controller 300. Thus the test mode decoder circuit 330 may detect a request for a test mode by evaluating the control data stored in the control registers 320.

A plurality of test modes may be used to effect complete testing of the control registers 320. For example, first control data that is undefined or otherwise not used during normal operation may be written to a first control register 322 to enable a first test mode that allows testing of the other control registers. The first test mode may be enabled so long as the first control data is retained in the first control register 322. However, the first test mode may not be effective to test the first control register 322 since the first control data must be maintained. To test the first control register 322, second control data that is undefined or otherwise not used during normal operation may be written to a second control register 324 to enable a second test mode that allows testing of the first control register. The second test mode may be enabled so long as the second control data is retained in the second control register 324.

Once a test mode is enabled, a data selector circuit 340 may be enabled to select at least a portion of the data in the control registers 320 for verification. For example, the data selector circuit 340 may select a single bit from the contents of the control registers 320 as test data 318 for verification. The data selector circuit 340 may be a multiplexer, a shift register, or other logic circuits to select a single bit from the control registers 320. If, for example, the control registers 320 comprise four 16-bits registers storing a total of 64 bits, 6 of the address signals 312A may be coupled to the data selector circuit 340 to control which single bit is selected from the control registers 320.

During a test mode, the test data bit 318 selected by the data selector circuit 340 may be routed to the external system by multiplexer circuit 350. During a test mode, the multiplexer circuit 350 may simply substitute the test data 318 for the normal error output signal 316 from the circuits 310. During normal operation of the integrated circuit 300, the multiplexer circuit 350 may pass the normal error output signal 316 to the external system. The multiplexer circuit 350 may be a specific circuit, or may be implemented by routing the signals 316 and 318 onto a common signal bus using tri-state logic.

Description of Processes

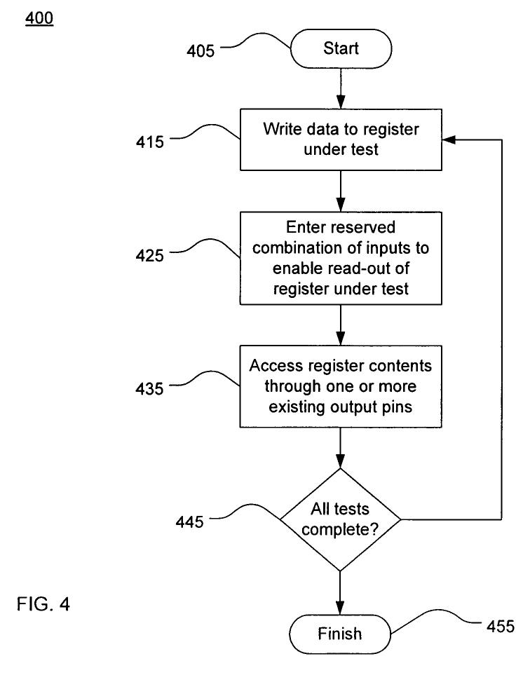

Referring now to FIG. 4, a process 400 for testing an integrated circuit has both a start 405 and an end 455, but the process 400 is cyclical in nature and may be repeated to test a plurality of write-only control registers within the integrated circuit. At 415, test data may be written to the control register to be tested. At 425, an undefined or otherwise unused combination of input signals may be applied to the integrated circuit to enable a test mode allowing read-out of the test data stored in the register under test. At 435, the contents of the register under test may be accessed through one or more existing output pins on the integrated circuit. The process may be repeated from 415 to 445 until the register under test has been completely tested.

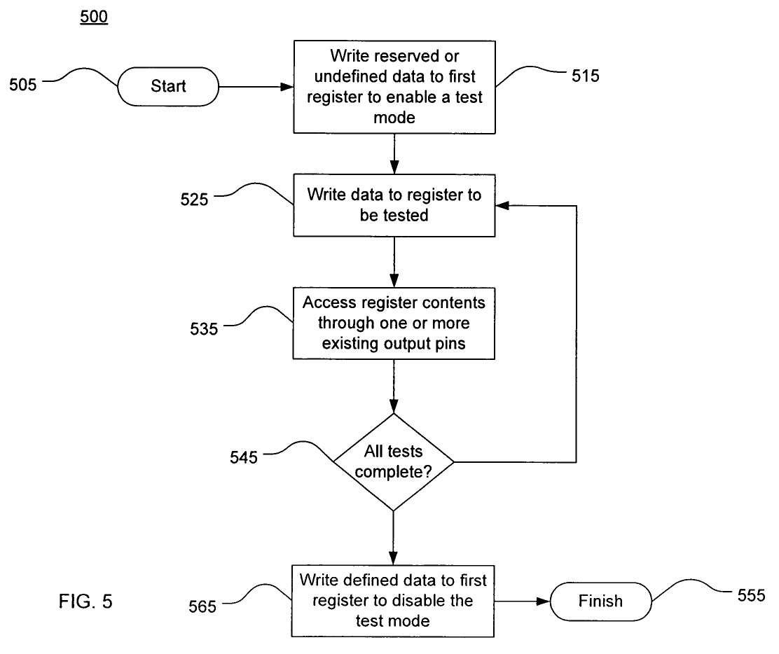

Referring now to FIG. 5, another process 500 for testing an integrated circuit has both a start 505 and an end 555, but is also cyclical in nature and may be repeated to test a plurality of write-only control registers within the integrated circuit. At 515, predetermined control data may be written to a first control register to enable a test mode. The predetermined control data may be undefined or otherwise unused during normal operation of the integrated circuit. The test mode may be enabled at long as the predetermined control data is stored in the first register. At 525, test data may be written into a register, other than the first register, to be tested. At 535, the contents of the register under test may be accessed through one or more existing output pins on the integrated circuit. The process may be repeated from 525 to 545 until the register under test has been completely tested. At 565, the test mode may be disabled by writing defined control data into the first control register.

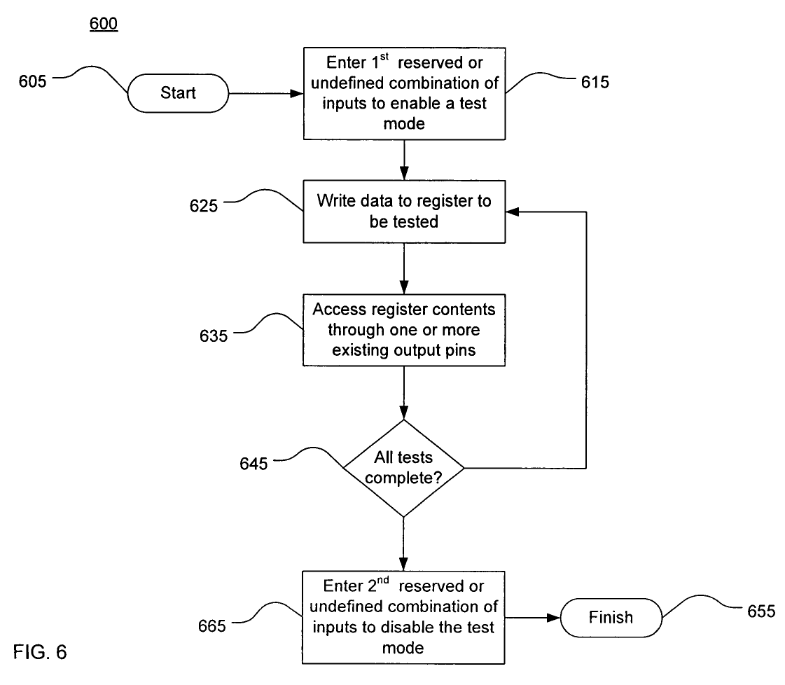

Referring now to FIG. 6, another process 600 for testing an integrated circuit has both a start 605 and an end 655, but is also cyclical in nature and may be repeated to test a plurality of write-only control registers within the integrated circuit. At 615, a first predetermined combination of input signals may be presented to the integrated circuit to enable a test mode. The predetermined combination of input signals may be undefined or otherwise unused during normal operation of the integrated circuit. The test mode may persist until it is disabled by a second predetermined combination of input signals. At 625, test data may be written into the register to be tested. At 635, the contents of the register under test may be accessed through one or more existing output pins on the integrated circuit. The process may be repeated from 625 to 645 until the register under test has been completely tested. At 665, the test mode may be disabled by presenting the second predetermined combination of input signals.

Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

For means-plus-function limitations recited in the claims, the means are not intended to be limited to the means disclosed herein for performing the recited function, but are intended to cover in scope any means, known now or later developed, for performing the recited function.

As used herein, “plurality” means two or more.

As used herein, a “set” of items may include one or more of such items.

As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

As used herein, “and/or” means that the listed items are alternatives, but the alternatives also include any combination of the listed items.

It is claimed:

1. An integrated circuit that receives a plurality of input signals and provides at least one output signal, comprising:
at least one output pin to provide the at least one output signal
one or more write-only control registers to store control data that controls, at least in part, the function of the integrated circuit
a test mode decoder circuit to enable a test mode
a data selector circuit to select at least a portion of the control data stored in the control registers as test data, the test data being output from the integrated circuit through at least one output pin when the test mode is enabled.

2. The integrated circuit of claim 1, further comprising a multiplexer circuit coupled to at least one output pin, the multiplexer circuit to output the test data when the test mode is enabled and to output the at least one output signal when the test mode is not enabled.

3. The integrated circuit of claim 1, wherein the test mode decoder circuit detects a first predetermined combination of input signals to enable a test mode, the first predetermined combination of input signals not otherwise used during operation of the integrated circuit.

4. The integrated circuit of claim 3, wherein, after the first predetermined combination of input signals is detected, a test mode is enabled until the test mode decoder circuit detects a second predetermined combination of input signals as a request to disable the test mode.

5. The integrated circuit of claim 1, wherein the test mode decoder circuit detects at least one predetermined combination of control data stored in a control register to enable test mode, the predetermined control data not otherwise used during operation of the integrated circuit.

6. A test circuit to test an integrated circuit, the integrated circuit containing at least one write-only register and providing at least one output signal through at least one output pin, the test circuit comprising
a test mode decoder circuit to enable a test mode
a data selector circuit to select at least a portion of data stored in the at least one write-only register as test data, the test data being output from the integrated circuit through the at least one output pin.

7. The test circuit of claim 6, further comprising a multiplexer circuit coupled to the at least one output pin, the multiplexer circuit to output the test data when the test mode is enabled and to output the at least one output signal when the test mode is not enabled.

8. The test circuit of claim 6, wherein the test mode decoder circuit detects a first predetermined combination of input signals to enable a test mode, the combination of input signals not otherwise used during operation of the integrated circuit.

9. The integrated circuit of claim 8, wherein, after the first predetermined combination of input signals is detected, a test mode is enabled until the test mode decoder circuit detects a second predetermined combination of input signals as a request to disable the test mode.

10. The integrated circuit of claim 6, wherein the test mode decoder circuit detects at least one predetermined combination of data stored in a write-only register as a request to enable test mode, the predetermined stored data not otherwise used during operation of the integrated circuit.

11. A process for testing an integrated circuit containing write-only registers, comprising:
writing test data to a write-only register
enabling a test mode
after writing test data and enabling a test mode, selecting one or more bits from the write only register as test data
outputting the test data from the integrated circuit through at least one existing output pin.

12. The process for testing an integrated circuit containing write-only registers of claim 11, wherein enabling a test mode comprises detecting a first predetermined combination of input signals, the first predetermined combination of input signals not otherwise used during operation of the integrated circuit.

13. The process for testing an integrated circuit containing write-only registers of claim 12, wherein, after the first predetermined combination of input signals is detected to enable a test mode, the test mode remains enabled until a second predetermined combination of input signals is detected to disable the test mode.

14. The process for testing an integrated circuit containing write-only registers of claim 11, wherein enabling a test mode comprises detecting at least one predetermined combination of control data stored in a control register as a request to enable test mode, the predetermined control data not otherwise used during operation of the integrated circuit.
